(19) United States
(12) Patent Application Publication
(10) Pub. No.: US 2025/0006630 A1
(43) Pub. Date: Jan. 2, 2025

(54) Routing and Passive Components in a Direct Bonding Layer

(71) Applicant: Intel Corporation, Santa Clara, CA (US)

(72) Inventors: Carla Moran Guizan, Munich (DE); Peter Baumgartner, Munich (DE); Thomas Wagner, Regelsbach (DE); Georg Seidemann, Landshut (DE); Michael Langenbuch, Munich (DE); Mamatha Yakkegondi Virupakshappa, Munich (DE); Jonathan Jensen, Portland, OR (US); Roshini Sachithanandan, Munich (DE); Philipp Riess, Munich (DE)

(73) Assignee: Intel Corporation, Santa Clara, CA (US)

(21) Appl. No.: 18/342,130

(22) Filed: Jun. 27, 2023

(51) Int. Cl. H01L 23/522; H01L 23/00; H01L 23/528; H01L 25/065

(52) U.S. Cl. CPC H01L 23/5227; H01L 23/528; H01L 24/08; H01L 25/0657; H01L 2224/08145

(57) ABSTRACT

Described herein are integrated circuit devices that include conductive structures formed by direct bonding of different components, e.g., direct bonding of two dies, or of a die to a wafer. The conductive structures are formed from a top metallization layer of each of the components. For example, elongated conductive structures at the top metallization layer may be patterned and bonded to form large interconnects for high-frequency and/or high-power signals. In another example, the bonded conductive structures may form radio frequency passive devices, such as inductors or transformers.

### TECHNICAL FIELD

This disclosure relates generally to the field of integrated circuit (IC) structures and devices, and more specifically, to conductive structures in multi-die IC packages.

### BACKGROUND

Multi-die chips are being increasingly used for high performance computing systems. In multi-die packages, several dies are mounted together in a bigger die or interposer. One way to merge the dies is to use copper bonding, also referred to as hybrid bonding or direct bonding. This technique uses the top metal layer at the face of each die to provide bonding pads, and then mounts the dies face-to-face. When using the top layers of the dies to bond the dies, the routing area within each die is reduced, since the top layers are used only to provide pads to interconnect the dies and are not used for routing signals within each die.

In IC dies, the top two or three layers of a die are typically thicker than the rest of the metal stack. These thick layers can be used for radio frequency (RF) systems and high-speed and high-power routing. Furthermore, passive components like inductors or transmission lines achieve better performance in the thicker layers than in the lower, thinner layers, due to lower resistance of the thicker metal lines. Using the thick top layer for die-to-die bonding limits the area that can be used for RF components and high-power and high-speed routing.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-section showing a die coupled to another die at a direct bonding interface, according to some embodiments of the present disclosure.

FIG. 1B is a cross-section showing a die coupled to a wafer a direct bonding interface, according to some embodiments of the present disclosure.

FIGS. 2A and 2B are two cross-sections of example direct bonds for routing or passive components, according to some embodiments of the present disclosure.

FIGS. 3A-3C are three cross-sections of example direct bonds where the metal includes offset holes, according to some embodiments of the present disclosure.

FIGS. 4A-4C are three cross-sections of example direct bonds where an electrical signal passes between and along the two components, according to some embodiments of the present disclosure.

FIGS. 5A and 5B are a cross-section and a perspective illustration, respectively, of a conductive path that moves between the bonding layer and a lower metal layer of one of the components, according to some embodiments of the present disclosure.

FIG. 6 is a perspective illustration of an inductor formed partially within a direct bonding interface, according to some embodiments of the present disclosure.

FIGS. 7A and 7B are top views of a wafer and dies that may include a direct bonding interface incorporating routing or passive devices, in accordance with any of the embodiments disclosed herein.

FIG. 8 is a cross-sectional side view of an IC device that may form a part of a die or other component that bonded to another component in a direct bonding interface incorporating routing or passive devices in accordance with any of the embodiments disclosed herein.

FIG. 9 is a cross-sectional side view of an IC device assembly that may include a direct bonding interface incorporating routing or passive devices in accordance with any of the embodiments disclosed herein.

FIG. 10 is a block diagram of an example computing device that may include a direct bonding interface incorporating routing or passive devices in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Direct bonding has gotten attention recently for coupling microelectronic components (e.g., two dies, or a die and one of a package substrate, a circuit board, or an interposer). As used herein, the term “direct bonding” is used to include metal-to-metal bonding techniques (e.g., copper-to-copper bonding, or other techniques in which direct bonding contacts (DB contacts) of opposing direct bonding interfaces (DB interfaces) are brought into contact first, then subject to heat and compression) and hybrid bonding techniques (e.g., techniques in which direct bonding dielectric (DB dielectric) of opposing DB interfaces, possibly first subjected to prior surface activation, are brought into contact first, then subject to heat and sometimes compression, or techniques in which the DB contacts and the DB dielectric, possibly first subjected to prior surface activation, of opposing DB interfaces are brought into contact substantially simultaneously, and the subject to heat and sometimes compression). The materials of opposing DB dielectrics can be homogeneous (i.e., have substantially the same material composition) or non-homogeneous (i.e., have different material compositions). In such techniques, the DB contacts, and the DB dielectric at one DB interface (e.g., at a DB interface of a first microelectronic component) are brought into contact with the DB contacts and the DB dielectric at another DB interface (e.g., at a DB interface of a second microelectronic component), respectively, and elevated pressures and/or temperatures may be applied to cause the contacting DB contacts and/or the contacting DB dielectrics to bond.

The DB contacts are typically bonding pads, which may have square or circular shapes when viewed from the face of the IC component. For example, DB pads are often copper pillars formed in dielectric. The bonding pads provide signal and/or power connections between the components joined at the DB interface. For example, each bonding pad may be coupled to one or more interconnects in lower metal layers in each of the components.

Direct bonding may provide significant advantages over conventional coupling techniques such as solder-based interconnects or wirebonds. Direct bonding interconnects may be capable of reliably conducting a higher current than other types of interconnects; for example, some conventional solder interconnects may form large volumes of brittle intermetallic compounds when current flows, and the maximum current provided through such interconnects may be constrained to mitigate mechanical failure.

Direct bonding uses the metal top layer at the face of each component to provide the DB contacts. In a single-die package, the top metal layer is typically used for routing within the die and/or for RF components, such as inductors, transformers, filters, etc. As noted above, in IC dies, the top layer or top several layers of a die are typically thicker than layers in the rest of the metal stack, which makes these upper layers particularly well-suited for RF components and high-speed and high-power routing. By using the top metal layer to provide the DB contacts rather than for routing or RF components, the space in the die available for these structures is reduced.

As described herein, rather than using bonding pads (e.g., pillar-shaped pads) to provide direct bonding of conductive structures, the DB contacts may be elongated conductive structures extending along the plane of the DB interface. These elongated DB contacts are also referred to herein as interconnects, DB interconnects, conductive structures, or DB conductive structures. The DB interconnects may be substantially overlapping, providing routing paths with large cross-sections (e.g., twice the height of a routing path in the top layer, since the routing path is formed from the top layer of each die) at the bonding interface. High-speed and/or high-power routing would benefit from the extra thickness and reduced resistance of the bonding traces. In other examples, DB interconnects may be partially overlapping structures, where the conductive pathway may move back and forth between the two components. The DB interconnects (or, more generally, DB conductive structures) may be used to form various types of transmission lines, including coplanar waveguides or microstrips. In some embodiments, the DB conductive structures may form RF passive devices within or partially within the bonding interface. For example, the DB conductive structures used to join two dies can be shaped to form an inductor, a transformer, or a passive filter.

In the following detailed description, various aspects of the illustrative implementations will be described using terms commonly employed by those skilled in the art to convey the substance of their work to others skilled in the art.

For example, the term “interconnect” may be used to describe any element formed of an electrically conductive material for providing electrical connectivity to one or more components associated with an IC or/and between various such components. In general, the term “interconnect” may refer to both conductive traces (also sometimes referred to as “lines” or “trench contacts”) and conductive vias. In general, in context of interconnects, the term “conductive trace” may be used to describe an electrically conductive element isolated by an insulator material (e.g., a low-k dielectric material) that is provided within the plane of an IC die. Such traces are typically stacked into several levels, or several layers, of metallization stacks. On the other hand, the term “via” may be used to describe an electrically conductive element that interconnects two or more traces of different levels. To that end, a via may be provided substantially perpendicularly to the plane of an IC die and may interconnect two traces in adjacent levels or two traces in not adjacent levels. A term “metallization stack” may be used to refer to a stack of one or more interconnects for providing connectivity to different circuit components of an IC chip. Sometimes, traces and vias may be referred to as “conductive traces” and “conductive vias”, respectively, to highlight the fact that these elements include electrically conductive materials such as metals.

Interconnects as described herein, in particular interconnects formed at a bonding layer as described herein, may be used for providing connectivity to one or more components associated with an IC or/and between various such components, where, in various embodiments, components associated with an IC may include, for example, transistors, diodes, power sources, resistors, capacitors, inductors, transformers, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

In another example, the terms “package” and “IC package” are synonymous, as are the terms “die” and “IC die,” the term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. The term “circuit” may be used to describe one or more passive and/or active components that are arranged to cooperate with one another to provide a desired function.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

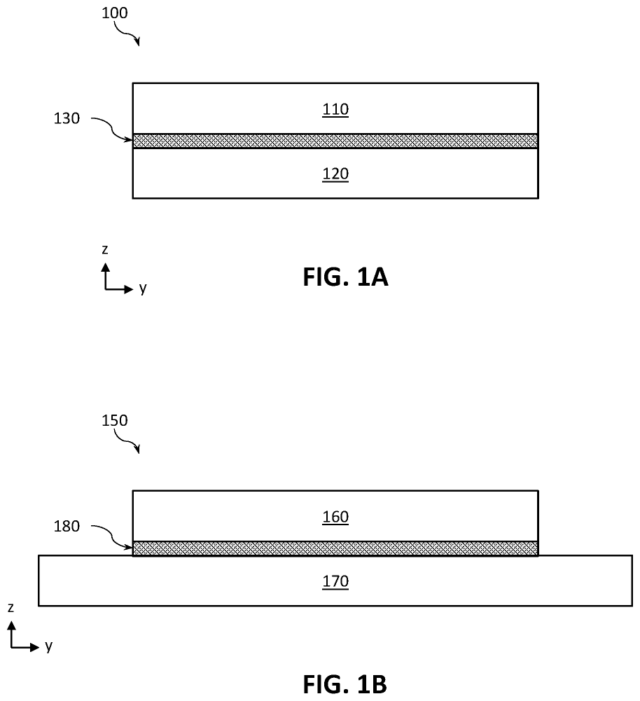

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 1A-1B, such a collection may be referred to herein without the letters, e.g., as “FIG. 1.”

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

Example Assemblies with Components Coupled by Direct Bonding

The embodiments described herein apply to direct bonding of electronic components. In different embodiments, different types of electronic components may be assembled together using direct bonding. For example, a die may be coupled to another die, to a wafer, to a package substrate, to a circuit board, or to an interposer. As another example, a wafer may be coupled to another wafer. In general, the conductive structures described herein may be included at a direct bonding interface between any combination of electronic components.

As described above, the term “direct bonding” is used to include metal-to-metal bonding techniques such as copper-to-copper bonding, or other techniques in which the conductive structures at opposing surfaces of electronic components are brought into contact first, then subject to heat and compression. The term “direct bonding” is also used to include hybrid bonding techniques, which include techniques in which the dielectric materials at opposing surfaces, possibly first subjected to prior surface activation, are brought into contact and then subjected to heat and sometimes compression, and techniques in which the conductive structures and dielectric materials of opposing surfaces, possibly first subjected to prior surface activation, are brought into contact substantially simultaneously, then subject to heat and sometimes compression. In some embodiments, the bonding may be achieved without the use of intervening solder or an anisotropic conductive material. In some other embodiments, a thin cap of solder may be used between the conductive structures to accommodate planarity, and this solder may become an intermetallic compound in the bonding interface during processing.

FIG. 1 illustrates two examples of direct bonds between electronic components. FIG. 1A is a cross-section showing a die coupled to another die at a direct bonding interface, according to some embodiments of the present disclosure. In particular, FIG. 1A illustrates an assembly 100 that includes a first die 110 and a second die 120. The first die 110 and the second die 120 are coupled at a bonding interface 130. The bonding interface 130 may be a direct bonding interface, as described above.

FIG. 1B is a cross-section showing a die coupled to a wafer a direct bonding interface, according to some embodiments of the present disclosure. In particular, FIG. 1B illustrates an assembly 150 that includes a die 160 and a wafer 170. The die 160 and the wafer 170 are coupled at a bonding interface 180. The bonding interface 180 may be a direct bonding interface, as described above. While one die 160 is illustrated as being coupled to the wafer 170, in other embodiments, one or more additional dies may be coupled to the wafer 170 in direct bonding interfaces or using other types of bonding or coupling.

In general, the assemblies described herein may include one or more support structures. For example, each die and/or wafer may include a support structure on a side opposite the bonding interface. The support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device that can include a direct bonding interface incorporating routing or passive devices, as described herein, may be built falls within the spirit and scope of the present disclosure.

In some embodiments, various layers may be formed over each support structure. For example, the die 110 and the die 120 may each include one or more device layers and a set of metallization layers formed over a respective support structure. The die 110 may be arranged with the support structure at the top in the orientation shown, and the “top” metallization layers at the bottom in the orientation shown. Thus, the die 110 may be flipped from an orientation for fabricating the die 110. The die 120 may be arranged with the support structure at the bottom in the orientation shown, and the top metallization at the top of the die 120 in the orientation shown. Thus, the “top” metal layers of the dies 110 and 120 come into contact at the bonding interface 130. The die 160 and the wafer 170 may be arranged in a similar manner, with the “top” metal layers of the die 160 and wafer 170 coming into contact at the bonding interface 180.

### Example Structures Formed by Direct Bonding

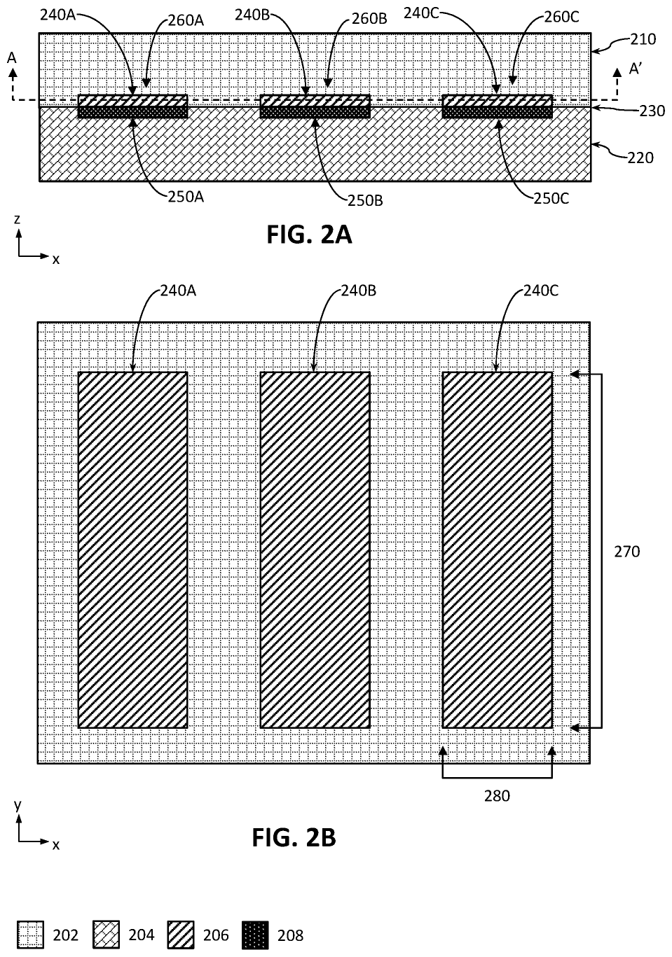

FIGS. 2-6 provide examples of IC devices that include features, such as interconnects and passive devices, that are formed by direct bonding of elongated conductive structures. Different regions of the IC devices are indicated by different patterns, with a legend showing the correspondence between the reference numerals and patterns being provided at the bottom of the drawing pages. Certain patterns are used throughout FIGS. 2-6 to refer to different materials or regions. For example, the legend for FIG. 2 illustrates that the different patterns show a dielectric 202 of a first component (e.g., a first die or first wafer), a dielectric 204 of a second component (e.g., a second die or second wafer), a conductive material 206 of the first component, and a conductive material 208 of the second component.

The dielectrics 202 and 204 may include one or more dielectric materials, such as one or more inorganic dielectric materials. For example, each of the dielectrics 202 and 204 may include silicon, carbon, and nitrogen (e.g., in the form of silicon carbon nitride); silicon and nitrogen (e.g., in the form of silicon nitride); silicon and oxygen (e.g., in the form of silicon oxide); carbon and oxygen (e.g., in the form of a carbon-doped oxide); silicon, oxygen, and nitrogen (e.g., in the form of silicon oxynitride); aluminum and oxygen (e.g., in the form of aluminum oxide); titanium and oxygen (e.g., in the form of titanium oxide); hafnium and oxygen (e.g., in the form of hafnium oxide); silicon, oxygen, carbon, and hydrogen (e.g., in the form of tetraethyl orthosilicate (TEOS)); zirconium and oxygen (e.g., in the form of zirconium oxide); niobium and oxygen (e.g., in the form of niobium oxide); tantalum and oxygen (e.g., in the form of tantalum oxide); and combinations thereof. In some embodiments, a given component (e.g., a wafer or a die) includes multiple layers of dielectric materials, where the dielectric materials may be the same or different in different layers. In some embodiments, a layer of a dielectric 202 or 204 closest to a bonding surface of a direct bonding interface (e.g., closer to the bonding interface 230) may have a higher carbon content than other layers of dielectric. While the dielectrics 202 and 204 are illustrated with different patterns, in some embodiments, the dielectrics 202 and 204 may include the same materials.

The conductive materials 206 and 208 may include any one or more conductive materials, such as copper (e.g., PCC or FGC), manganese, titanium, gold, silver, palladium, nickel, aluminum, copper and aluminum (e.g., in the form of a copper aluminum alloy), tantalum (e.g., tantalum metal, or tantalum and nitrogen in the form of tantalum nitride), cobalt, cobalt and iron (e.g., in the form of a cobalt iron alloy), or any alloys of any of the foregoing (e.g., copper, manganese, and nickel in the form of manganin). While the conductive materials 206 and 208 are illustrated with different patterns, in some embodiments, the conductive materials 206 and 208 may include the same material or materials, e.g., both conductive materials 206 and 208 may be copper.

FIGS. 2A and 2B are two cross-sections of example direct bonds for routing or passive components, according to some embodiments of the present disclosure. FIG. 2B is a cross-section through the plane AA′ in FIG. 2A. FIG. 2A illustrates two components 210 and 220. Each of the components 210 and 220 may be any of the components that can be directly bonded as described above. For example, the component 210 may be the die 110 or the die 160, and the component 220 may be the die 120 or the wafer 170. The components 210 and 220 are joined at a bonding interface 230, which may be an example of the bonding interface 130 or the bonding interface 180. The bonding interface 230 is a plane that extends in the x and y directions in the example coordinate system; the AA′ plane shown in FIG. 2B is parallel to the x-y plane and parallel to the plane of the bonding interface 230.

The component 210 includes the dielectric 202 and the conductive material 206. The component 220 includes the dielectric 204 and the conductive material 208. As noted above, while the dielectrics 202 and 204 of the respective components 210 and 220 are illustrated using different patterns, in some embodiments, the dielectrics 202 and 204 may be the same dielectric material. Furthermore, while the conductive materials 206 and 208 of the respective components 210 and 220 are illustrated using different patterns, in some embodiments, the conductive materials 206 and 208 may be the same conductive material (e.g., copper). In a cross-section of a device (e.g., a TEM image), the boundary between the conductive materials 206 and 208 may be visible, e.g., as a seam, even if the materials 206 and 208 are the same. Furthermore, the boundary between the dielectrics 202 and 204 may be visible, e.g., as a seam, or through the presence of an additional material layer formed from a bonding material (e.g., a bonding oxide).

The conductive material 206 is in a top metallization layer of the component 210. The component 210 has been flipped onto the component 220, so that the top metallization layer (which may be a last-formed metallization layer in a fabrication process) is on the bottom of the component 210 in the orientation shown. Likewise, the conductive material 208 is in a top metallization layer of the component 220 (both in the orientation shown and during the fabrication process). The conductive materials 206 and 208 illustrated in FIG. 2 form trench structures. For example, as shown in FIG. 2B, the conductive material 206 is formed into three trenches 240A-240C, where each of the trenches extends in the y-direction in the example coordinate system shown. In other words, the trenches 240A-240C extend along the plane of the bonding interface 230, which as noted above, extends in the y-direction (and the x-direction).

Each of the trench structures 240 and 250 has a length and a width, where the length is the longer dimension of the trench structure in the plane of the bonding interface 230 (i.e., the x-y plane in the example coordinate system), and the width is the shorter dimension of the trench structure in the plane of the bonding interface. FIG. 2B illustrates a length 270 and a width 280 of the trench structure 240C. The length 270 may be, for example, at least twice, three times, five times, or ten times the width 280. For different routing arrangements, different trench structures may have different lengths, e.g., the trench structure 240B may have a shorter length than the length 270 of the trench structure 240C. In some examples, different trench structures may have different widths.

The conductive material 208 is formed into three trenches 250A-250C, where each of the trenches extends in the y-direction in the example coordinate system shown. The trenches 250A-250C may have similar shapes and sizes to the trenches 240A-240C.

In this example, the trench structures formed by the conductive materials 206 and 208 are substantially overlapping. For example, the trench structure 240A in the component 210 is formed over trench structure 250A in the component 220. Each of the trench structures 240 and 250 may be considered an interconnect structure, e.g., an interconnect formed in a top metal layer. The trench structures 240 and 250 are bonded to form bonded interconnect structures 260; for example, trench structures 240A and 250 together form a bonded interconnect structure 260A. Each bonded interconnect structure 260 has a large cross-section; for example, the cross-sectional area of the bonded interconnect structure 260A is a sum of the cross-sectional areas of the trench structures 240A and 250A. The cross-sectional area of a bonded interconnect structure 260 is generally larger than a cross-sectional area of an interconnect formed in the top metallization layer of a component, e.g., larger than the cross-sectional area of the trench structure 240A or the cross-sectional area of the trench structure 250A. This large cross-sectional area may make the bonded interconnect structures 260 particularly well suited for certain applications, such as routing of high-power signals and routing of high-frequency signals, e.g., RF signals.

In some embodiments, the bonded interconnect structures 260 form signal routing structures. In some embodiments, the bonded interconnect structures 260 (or, more generally, bonded conductive structures 260) are formed into a passive device, such as an inductor, a filter, or a transformer.

In some embodiments, the bonded interconnect structures 260 may form a coplanar waveguide. For example, the bonded interconnect structures 260B may be a signal path of a coplanar waveguide, while the bonded interconnect structures 260A and 260C on either side of the signal path 260B are ground planes. In the coplanar waveguide example, the ground planes 260A and 260C are separated from the signal path 260B by dielectric materials, i.e., the dielectric materials 202 and 204.

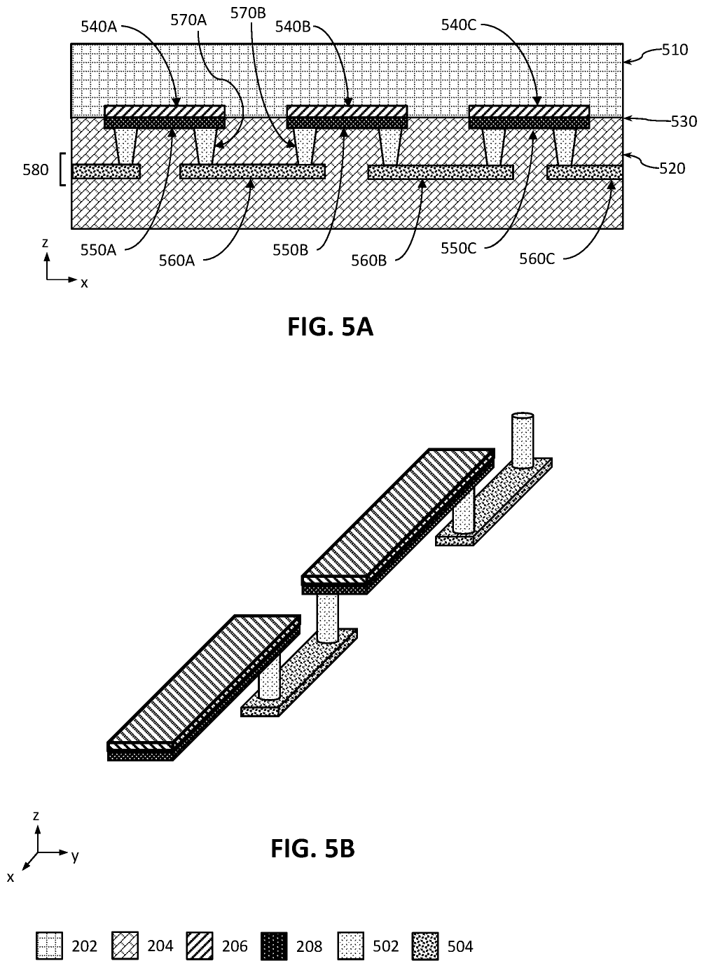

The cross-section of the component 210 and/or the component 220 may include various additional features not illustrated in FIG. 2A. For example, the component 210 may include additional metal layers above (in the orientation of FIG. 2A, or below during fabrication) the conductive material 206. The component 210 may include one or more via structures extending in the z-direction, where the via structures couple the conductive material 206 to other metallization layers, e.g., as illustrated in FIG. 5. The vias may provide signal routing to other portions of the component 210. The component 210 may further include one or more device layers above (in the orientation of FIG. 2A, or below during fabrication) the conductive material 206. The device layers may include transistors, capacitors, memory devices, etc. The component 210 may further include a substrate or other support structure above (in the orientation of FIG. 2A, or below during fabrication) the conductive material 206. While the dielectric 202 is illustrated as extending from the bottom to the top of the component 210, it should be understood that one or more layers of different dielectric materials may be included in the component 210. Furthermore, a support structure formed from a different material (e.g., silicon or another semiconductor material) may be included in the component 210.

Likewise, the component 220 may include additional metallization layers below the conductive material 208, with trench structures extending in the x- and/or y-directions in different layers, and via structures extending between layers in the z-direction. The component 220 may further include one or more device layers and/or a substrate or other support structure, as described above.

While the trench structures 240 and 250 illustrated in FIG. 2 are illustrated as being formed from solid regions of the conductive materials 206 and 208, in other examples, vacant structures, referred to as holes, are formed in the trenches 240 and/or 250. Including holes in large conductive structures reduces metal density across the bonding layer, which may be useful for conforming to design rules for fabrication of upper metal layers. The holes in the conductive materials 206 and 208 may be arranged so that they are offset from each other, e.g., so that the holes are not overlapping.

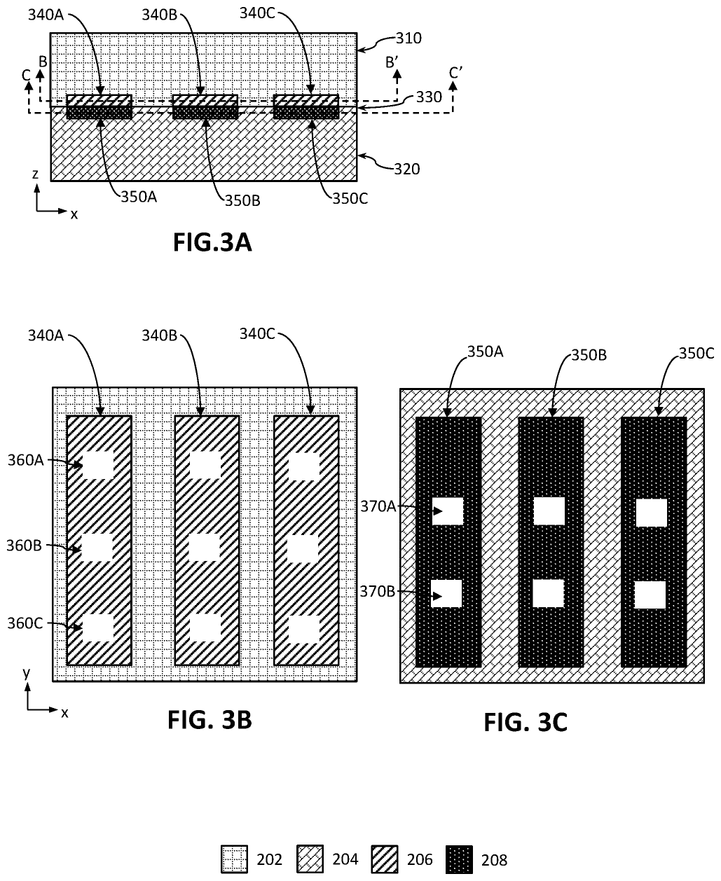

FIGS. 3A-3C are three cross-sections of example direct bonds where the conductive material includes offset holes, according to some embodiments of the present disclosure. FIG. 3B is a cross-section through the plane BB′ in FIG. 3A, and FIG. 3C is a cross-section though the plane CC′ in FIG. 3A. FIG. 3 illustrates two components 310 and 320 bonded at a bonding interface 330. Each of the components 310 and 320 may be any of the components that can be directly bonded as described above. For example, the components 310 and 320 may be similar to the components 210 and 220, described above. The component 310 and/or the component 320 may include various additional features (e.g., metallization layers, device layers, memory layers, support structures, etc.) not illustrated in FIG. 3.

The component 310 includes the conductive material 206 in a top metallization layer of the component 310; the conductive material 206 is at the bottom of the component 310 in the orientation shown. Likewise, the component 320 includes the conductive material 208 in a top metallization layer of the component 320. The conductive materials 206 and 208 illustrated in FIG. 3 form trench structures 340 and 350, which have a similar shape and arrangement to the trench structures 240 and 250, described above. In this example, each of the trench structures 340 includes holes 360, and each of the trench structures 350 includes holes 370. For example, the trench structure 340A includes holes 360A, 360B, and 360C, while the trench structure 350A includes holes 370A and 370B. The holes 360 and 370 may be vacancies in the conductive materials 206 and 208, or the holes 360 and 370 may be filled by a different material, e.g., a dielectric material. The holes 360 and 370 are offset from each other in the y-direction. For example, in the y-direction, the hole 370A is between the holes 360A and 360B. Thus, when the trench structures 340A and 350A are bonded as illustrated in FIG. 3A, the holes 360 are offset from and not overlapping with the holes 370. In other examples, the holes 360 and 370 in the bonded trench structures 340 and 350 may be substantially overlapping or partially overlapping.

In the examples of FIGS. 2 and 3, the bonded interconnect structures are substantially overlapping, e.g., to form a thick routing path or large conductive structure. In other examples, trench structures in two bonded components may be partially overlapping in an alternating fashion, e.g., to providing a routing path in which a signal passes back and forth between the two components, or to provide a conductive path for an inductor or other passive device where the conductive path moves between the two components.

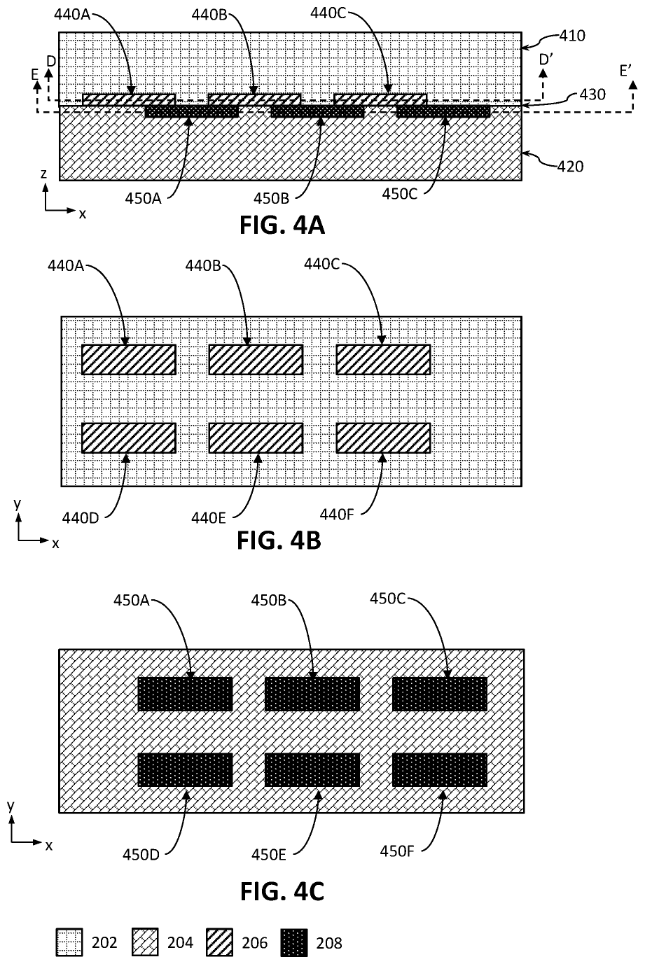

FIGS. 4A-4C are three cross-sections of example direct bonds where an electrical signal passes between and along the two components, according to some embodiments of the present disclosure. FIG. 4B is a cross-section through the plane DD′ in FIG. 4A, and FIG. 4C is a cross-section though the plane EE′ in FIG. 4A. FIG. 4 illustrates two components 410 and 420 bonded at a bonding interface 430. Each of the components 410 and 420 may be any of the components that can be directly bonded as described above. For example, the components 410 and 420 may be similar to the components 210 and 220, described above. The component 410 and/or the component 420 may include various additional features (e.g., metallization layers, device layers, memory layers, support structures, etc.) not illustrated in FIG. 4, as described above with respect to FIG. 2.

The component 410 includes the conductive material 206 in a top metallization layer of the component 410; the conductive material 206 is at the bottom of the component 410 in the orientation shown. Likewise, the component 420 includes the conductive material 208 in a top metallization layer of the component 420. The conductive materials 206 and 208 illustrated in FIG. 4 form trench structures 440 and 450, respectively.

For example, as shown in FIG. 4B, the conductive material 206 is formed into two rows of trenches 440, each row extending in the x-direction in the example coordinate system shown. A first row includes the three trenches 440A-440C, and a second row includes the three trenches 440D-440F. The first row of trenches 440A-440C is also illustrated in FIG. 4A. Each of the trenches 440 extends in the x-direction. The trenches 440A-440F extend in a direction parallel to the bonding interface 430, which as noted above, extends in the x-direction (and the y-direction). As shown in FIG. 4C, the conductive material 208 is formed into two rows of trenches 450, each row extending in the x-direction in the example coordinate system shown. A first row includes the three trenches 450A-450C, and a second row includes the three trenches 450D-450F. The first row of trenches 450A-450C is also illustrated in FIG. 4A.

The trenches 450 are offset from the trenches 440 in the x-direction. For example, as illustrated in FIG. 4A, the trenches 440A and 440B are each partially overlapping the trench 450A. The trench 450A is coupled to and extends between the trenches 440A and 440B. Thus, the trench 450A electrically couples the trenches 440A and 440B. Similarly, the trench 440B electrically couples the trenches 450A and 450B, and so on. The trenches 440A-440C and 450A-450C may provide a bonded interconnect structure that passes a signal along the bonding interface 430, where the signal moves back and forth between the components 410 and 420 along the trenches 440A-440C and 450A-450C. The trenches 440D-440F and 450D-450F may provide a separate bonded interconnect structure. In some embodiments, the bonded interconnect structures (or, more generally, bonded conductive structures) are formed into a passive device, such as an inductor, a filter, or a transformer.

Each of the trench structures 440 and 450 has a length and a width, where the length is the longer dimension of the trench structure in the plane of the bonding interface (i.e., the x-y plane in the example coordinate system), and the width is the shorter dimension of the trench structure in the plane of the bonding interface. In the orientation shown, the length is measured in the x-direction, and the width is measured in the y-direction. The length of a trench structure 440 or 450 may be, for example, at least twice, three times, five times, or ten times the width of the trench structure 440 or 450. For different routing arrangements, different trench structures may have different lengths and/or different widths.

In the examples shown in FIGS. 2-4, conductive pathways are formed from trenches at the bonding interface, i.e., bonded interconnect structures formed at the top metal layer. In other examples, a conductive pathway may extend into one or more additional metal layers, e.g., a lower metal layer on one of the dies. FIGS. 5A and 5B are a cross-section and a perspective illustration, respectively, of a conductive path that moves between the bonding layer and a lower metal layer of one of the components, according to some embodiments of the present disclosure. In the illustration of FIG. 5B, only the elements of the conductive pathway are shown, while the dielectrics 202 and 204 are omitted. FIG. 5B illustrates a portion of the trench structures and vias illustrated in FIG. 5A.

FIG. 5A illustrates two components 510 and 520 bonded at a bonding interface 530. Each of the components 510 and 520 may be any of the components that can be directly bonded as described above. For example, the components 510 and 520 may be similar to the components 210 and 220, described above.

The component 510 includes the conductive material 206 in a top metallization layer of the component 510; the conductive material 206 is at the bottom of the component 510 in the orientation shown. Likewise, the component 520 includes the conductive material 208 in a top metallization layer of the component 520. The conductive materials 206 and 208 illustrated in FIG. 5 form trench structures 540 and 550, respectively. The trench structures 540 and 550 may be similar to the trench structures 440 and 450 illustrated in FIG. 4 and described above. The trench structures 540 and 550 extend in the x-direction in the coordinate system shown. Unlike the trench structures 440 and 450 in FIG. 4, in this example, the trench structures 540 are aligned with the trench structures 550, such that the trench structures 540 are directly over the trench structures 550. Thus, the trench structures 540 and 550 form bonded interconnect structures, similar to the bonded interconnect structures 260 shown in FIG. 2.

FIG. 5A further illustrates a second metal layer 580 that includes trench structures 560. The trench structures 560 are formed from a conductive material 504, which may be the same material or a different material as the conductive material 208. The trench structures 560 extend in the x-direction in the coordinate system shown. The trench structures 560 extend in the same direction as (i.e., parallel to) the trench structures 540 and 550. The trench structures 560 are coupled to the trench structures 550 by vias 570. The vias 570 are formed from a via material 502, which may be any conductive material, e.g., the same conductive material as the trench structures 560 and/or 550, or a different conductive material.

For example, the trench structure 560A in the lower metal layer 580 is coupled to the trench structure 550A at the bonding interface 530 by the via 570A. The trench structure 560A is further coupled to the trench structure 550B by the via 570B. Thus, the trench structures 550A and 540A (which may be considered a first bonded interconnect structure) are electrically coupled to the trench structures 550B and 540B (which may be considered a second bonded interconnect structure) by the via 570A, the lower trench structure 560A, and the via 570B.

The component 510 and/or the component 520 may include various additional features (e.g., metallization layers, device layers, memory layers, support structures, etc.) not illustrated in FIG. 5. For example, the component 510A may have additional metallization layers below the metallization layer 580, and one or more device layers below the other metallization layers.

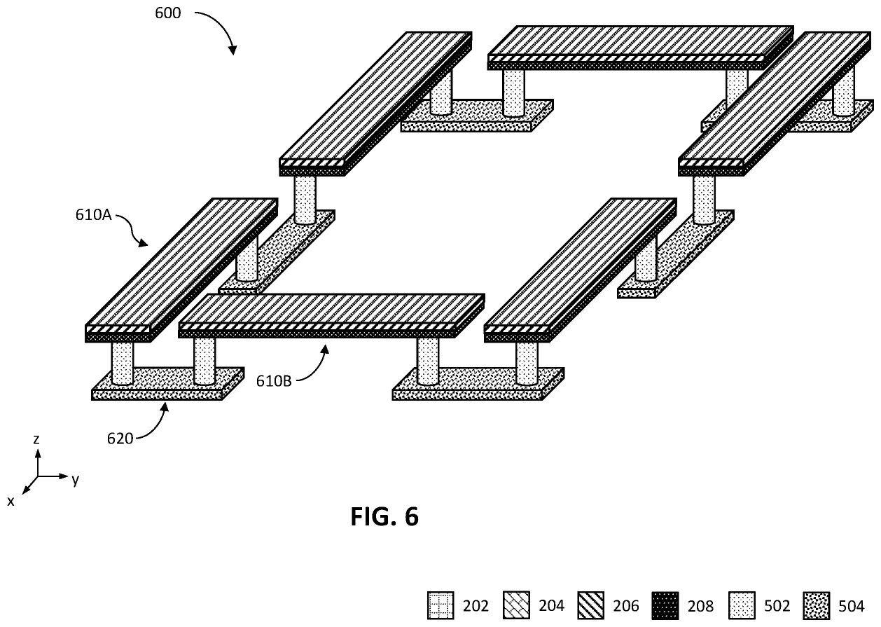

As noted above, the bonded interconnect structures and/or conductive paths that include bonded interconnect structures may be used to form various devices, such as RF passive devices. FIG. 6 is a perspective illustration of one example passive device, an inductor, formed partially within a direct bonding interface, according to some embodiments of the present disclosure. In this example, the inductor is a loop formed by bonded interconnect structures formed from the conductive materials 206 and 208. The loop is connected by vias and trenches in the lower metal layer, e.g., the vias 570 and trenches 560 shown in FIG. 5. This structure allows the inductor loop to move around the corners, where two bonded interconnect structures extend in perpendicular directions. For example, the bonded interconnect structure 610A extends in the x-direction in the coordinate system shown, and the bonded interconnect structure 610B extends in the y-direction. The bonded interconnect structures 610A and 610B are coupled together by the lower trench structure 620. In other examples, an inductor or other passive device may be formed by trench structures in the top metal layers of each component, e.g., using trench arrangements illustrated in any of FIGS. 2-5.

### Example Devices

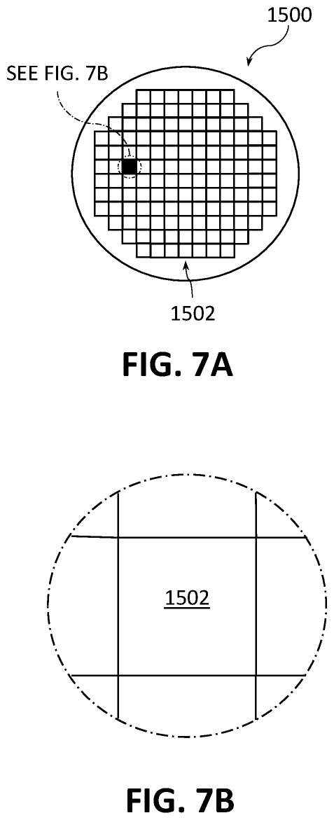

The direct bonding interface incorporating routing or passive devices disclosed herein may be included in any suitable electronic device. FIGS. 7-10 illustrate various examples of apparatuses that may include the direct bonding interface incorporating routing or passive devices disclosed herein, or that may be included in devices or assemblies that include a direct bonding interface incorporating routing or passive devices.

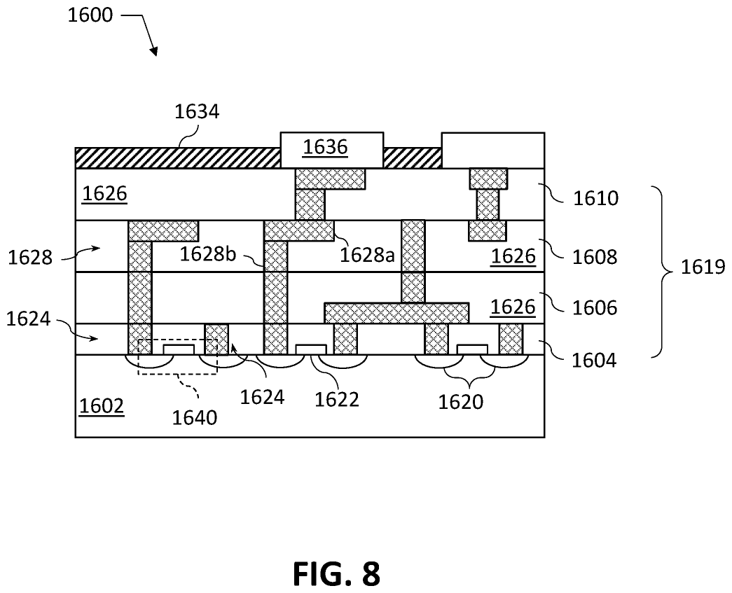

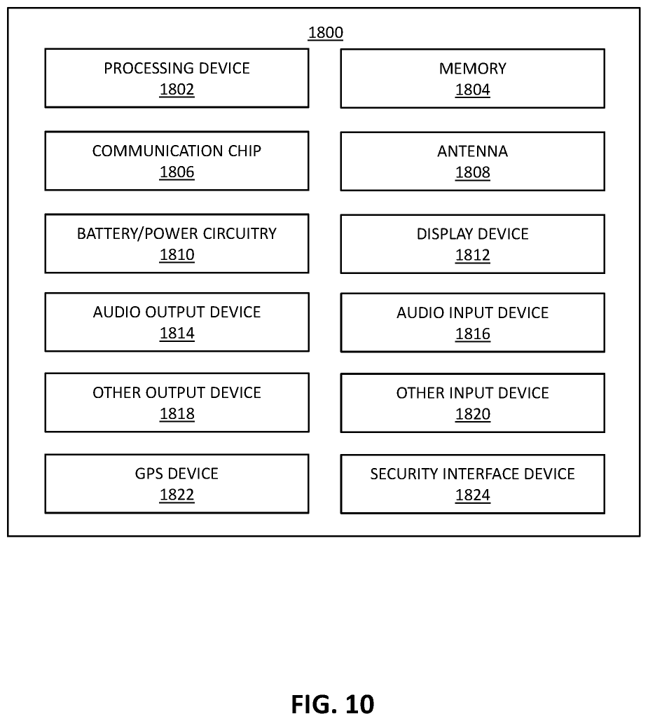

FIGS. 7A and 7B are top views of a wafer and dies that may include a direct bonding interface incorporating routing or passive devices in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIG. 1, 3, or 5, or any further embodiments of the IC structures described herein). After the fabrication of the semiconductor product is complete, the wafer 1500 may undergo a singulation process in which each of the dies 1502 is separated from one another to provide discrete “chips” of the semiconductor product. The die 1502 may include one or more transistors (e.g., one or more of the transistors 1640 of FIG. 8, discussed below) and/or supporting circuitry to route electrical signals to the transistors, as well as any other IC components. In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array. In various embodiments, the wafer 1500 and or one of the dies 1502 may be assembled with another wafer, die, or another component using direct bonding, as described above. The direct bonding interface may be a direct bonding interface incorporating routing or passive devices, e.g., as described with respect to FIGS. 1-6.

FIG. 8 is a cross-sectional side view of an IC device 1600 that may form a part of a die or other component that bonded to another component in a direct bonding interface incorporating routing or passive devices in accordance with any of the embodiments disclosed herein. The IC device 1600 may be formed on a substrate 1602 (e.g., the wafer 1500 of FIG. 7A) and may be included in a die (e.g., the die 1502 of FIG. 7B). The substrate 1602 may be any substrate as described herein. The substrate 1602 may be part of a singulated die (e.g., the dies 1502 of FIG. 7B) or a wafer (e.g., the wafer 1500 of FIG. 7A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 8 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 8). Although a particular number of interconnect layers 1606-1610 is depicted in FIG. 8, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 8. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 8. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

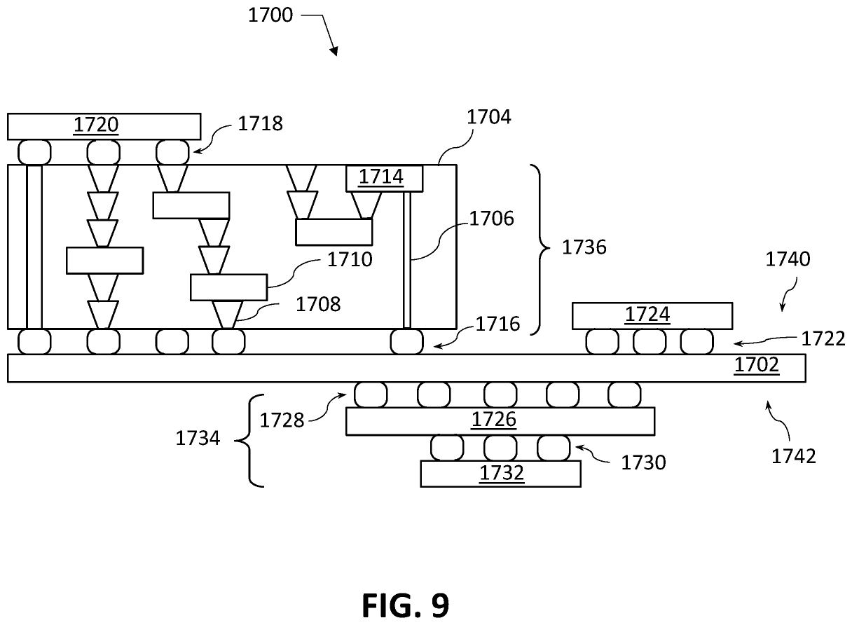

FIG. 9 is a cross-sectional side view of an IC device assembly 1700 that may include a direct bonding interface incorporating routing or passive devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may be bonded to another one of the components in a direct bonding interface incorporating routing or passive devices, as disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 7B), an IC device (e.g., the IC device 1600 of FIG. 8), or any other suitable component. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 9, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example computing device 1800 that may include a direct bonding interface incorporating routing or passive devices in accordance with any of the embodiments disclosed herein. For example, any suitable ones of the components of the computing device 1800 may include a die (e.g., the die 1502 of FIG. 7B) that is coupled via a direct bonding interface incorporating routing or passive devices to another component, as described herein. Any one or more of the components of the computing device 1800 may include, or be included in, an IC device 1600 (FIG. 8). Any one or more of the components of the computing device 1800 may include, or be included in, an IC device assembly 1700 (FIG. 9).

A number of components are illustrated in FIG. 10 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 10, but the computing device 1800 may include interface circuitry for coupling to the one or more components. For example, the computing device 1800 may not include a display device 1806, but may include display device interface circuitry (e.g., a connector and driver circuitry) to which a display device 1806 may be coupled. In another set of examples, the computing device 1800 may not include an audio input device 1824 or an audio output device 1808 but may include audio input or output device interface circuitry (e.g., connectors and supporting circuitry) to which an audio input device 1824 or audio output device 1808 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the computing device 1800 may include a communication chip 1812 (e.g., one or more communication chips). For example, the communication chip 1812 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The computing device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The computing device 1800 may include battery/power circuitry 1814. The battery/power circuitry 1814 may include one or more energy storage devices (e.g., batteries or capacitors) and/or circuitry for coupling components of the computing device 1800 to an energy source separate from the computing device 1800 (e.g., AC line power).

The computing device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1808 (or corresponding interface circuitry, as discussed above). The audio output device 1808 may include any device that generates an audible indicator, such as speakers, headsets, or earbuds, for example.

The computing device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The computing device 1800 may include a GPS device 1818 (or corresponding interface circuitry, as discussed above). The GPS device 1818 may be in communication with a satellite-based system and may receive a location of the computing device 1800, as known in the art.

The computing device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The computing device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides an IC device that includes a first die including a first metal layer at a lower face of the first die, the first metal layer having a first interconnect extending along the lower face, where the first interconnect has a length along the lower face and a width along the lower face, the length at least three times the width; a second die including a second metal layer at a upper face of the second die, the second metal layer having a second interconnect extending along the upper face of the second die; and a bonding interface coupling the first die to the second die, where the bonding interface couples the first interconnect to the second interconnect.

Example 2 provides the IC device of example 1, where the first interconnect is partially overlapping the second interconnect.

Example 3 provides the IC device of example 2, the first metal layer further including a third interconnect extending along the lower face, the third interconnect separated from the first interconnect, where the second interconnect couples the first interconnect to the third interconnect.

Example 4 provides the IC device of example 1, the first metal layer further including a third interconnect extending along the lower face, the third interconnect separated from the first interconnect, and the first die further including a second metal layer including a fourth interconnect, the fourth interconnect coupled to the first interconnect by a first via and the fourth interconnect coupled to the third interconnect by a second via.

Example 5 provides the IC device of example 1, where the first interconnect and the second interconnect form a signal path of a coplanar waveguide.

Example 6 provides the IC device of example 5, the first metal layer further including a third interconnect separated from the first interconnect and extending in parallel to the first interconnect, the second metal layer further including a fourth interconnect separated from the second interconnect and extending in parallel to the second interconnect, where the bonding interface couples the third interconnect to the fourth interconnect, the third interconnect and the fourth interconnect forming a ground structure of the coplanar waveguide.

Example 7 provides the IC device of any of the preceding examples, where the second interconnect has a second length along the upper face and a second width along the upper face, the second length at least three times the second width.

Example 8 provides the IC device of any of the preceding examples, where the first interconnect includes a metal having a first hole formed therein, and the second interconnect includes a metal having a second hole formed therein, the first hole offset from the second hole.

Example 9 provides the IC device of any of the preceding examples, where the first interconnect and the second interconnect form a side of an inductor, the inductor including additional pairs of coupled interconnects in the first die and the second die.

Example 10 provides the IC device of any of the preceding examples, where the bonding interface includes a seam formed between the first interconnect and the second interconnect.

Example 11 provides the IC device of any of the preceding examples, where the bonding interface further includes a bonding material formed between a first dielectric material in the first die and a second dielectric material in the second die.

Example 12 provides a device that includes a wafer having an upper face, the upper face of the wafer including a first trench interconnect extending along the upper face of the wafer; and a die including a metal layer at a lower face of the die, the metal layer having a second trench interconnect extending along the lower face of the wafer; where the first trench interconnect is physically coupled to the second trench interconnect.

Example 13 provides the device of example 12, where the first trench interconnect is partially overlapping the second trench interconnect.

Example 14 provides the device of example 13, where the upper face of the wafer further includes a third trench interconnect, the third trench interconnect separated from the first trench interconnect, where the second trench interconnect is further physically coupled to the third trench interconnect.

Example 15 provides the device of example 12, the die further including a second metal layer, the second metal layer above the lower face of the die, the second metal layer including a third interconnect coupled to the second interconnect by a via.

Example 16 provides the device of example 12, where the first trench interconnect and the second trench interconnect form a signal path of a coplanar waveguide.

Example 17 provides an electronics assembly that includes a first device including a first metal layer at a lower face of the first device; a second device including a second metal layer at an upper face of the first device; a bonding interface between the first metal layer and the second metal layer; and a passive circuit element including a first metal structure in the first metal layer and a second metal structure in the second metal layer, the first metal structure and the second metal structure bonded at the bonding interface.

Example 18 provides the electronics assembly of example 17, where the passive circuit element includes an inductor.

Example 19 provides the electronics assembly of example 18, where the passive circuit element is a transformer.

Example 20 provides the electronics assembly of example 17, where the passive circuit element is a filter.

Example 21 provides the electronics assembly of any of examples 17-19, where the passive circuit element is coupled to a third metal layer of the first device, the third metal layer above the first metal layer.

Example 22 provides the electronics assembly of example 21, where the passive circuit element is further coupled to a fourth metal layer of the second device, the fourth metal layer below the second metal layer.

Example 23 provides the electronics assembly of example 17, where the first device is a first die, and the second device is a second die.

Example 24 provides an IC package that includes an IC die, including one or more of the devices according to any one of the preceding examples. The IC package may also include a further component, coupled to the IC die.

Example 25 provides the IC package according to example 24, where the further component is one of a package substrate, a flexible substrate, or an interposer.

Example 26 provides the IC package according to examples 24 or 25, where the further component is coupled to the IC die via one or more first level interconnects.

Example 27 provides the IC package according to example 26, where the one or more first level interconnects include one or more solder bumps, solder posts, or bond wires.

Example 28 provides a computing device that includes a circuit board; and an IC die coupled to the circuit board, where the IC die includes one or more of the memory/IC devices according to any one of the preceding examples (e.g., memory/IC devices according to any one of examples 1-23), and/or the IC die is included in the IC package according to any one of the preceding examples (e.g., the IC package according to any one of examples 24-27).

Example 29 provides the computing device according to example 28, where the computing device is a wearable computing device (e.g., a smart watch) or hand-held computing device (e.g., a mobile phone).

Example 30 provides the computing device according to examples 28 or 29, where the computing device is a server processor.

Example 31 provides the computing device according to examples 28 or 29, where the computing device is a motherboard.

Example 32 provides the computing device according to any one of examples 28-31, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device comprising:
a first die comprising a first metal layer at a lower face of the first die, the first metal layer having a first interconnect extending along the lower face, wherein the first interconnect has a length along the lower face and a width along the lower face, the length at least three times the width;
a second die comprising a second metal layer at an upper face of the second die, the second metal layer having a second interconnect extending along the upper face of the second die; and
a bonding interface coupling the first die to the second die, wherein the bonding interface couples the first interconnect to the second interconnect.

2. The IC device of claim 1, wherein the first interconnect is partially overlapping the second interconnect.

3. The IC device of claim 2, the first metal layer further comprising a third interconnect extending along the lower face, the third interconnect separated from the first interconnect, wherein the second interconnect couples the first interconnect to the third interconnect.

4. The IC device of claim 1, the first metal layer further comprising a third interconnect extending along the lower face, the third interconnect separated from the first interconnect, and the first die further comprising a second metal layer comprising a fourth interconnect, the fourth interconnect coupled to the first interconnect by a first via and the fourth interconnect coupled to the third interconnect by a second via.

5. The IC device of claim 1, wherein the first interconnect and the second interconnect form a signal path of a coplanar waveguide.

6. The IC device of claim 5, the first metal layer further comprising a third interconnect separated from the first interconnect and extending in parallel to the first interconnect, the second metal layer further comprising a fourth interconnect separated from the second interconnect and extending in parallel to the second interconnect, wherein the bonding interface couples the third interconnect to the fourth interconnect, the third interconnect and the fourth interconnect forming a ground structure of the coplanar waveguide.

7. The IC device of claim 1, wherein the second interconnect has a second length along the upper face and a second width along the upper face, the second length at least three times the second width.

8. The IC device of claim 1, wherein the first interconnect comprises a metal having a first hole formed therein, and the second interconnect comprises a metal having a second hole formed therein, the first hole offset from the second hole.

9. The IC device of claim 1, wherein the first interconnect and the second interconnect form a side of an inductor, the inductor comprising additional pairs of coupled interconnects in the first die and the second die.

10. The IC device of claim 1, wherein the bonding interface comprises a seam formed between the first interconnect and the second interconnect.

11. The IC device of claim 1, wherein the bonding interface further comprises a bonding material formed between a first dielectric material in the first die and a second dielectric material in the second die.

12. A device comprising:
a wafer having an upper face, the upper face of the wafer comprising a first trench interconnect extending along the upper face of the wafer, wherein the first trench interconnect has a length along the upper face and a width along the upper face, the length at least three times the width; and
a die comprising a metal layer at a lower face of the die, the metal layer having a second trench interconnect extending along the lower face of the wafer;
wherein the first trench interconnect is physically coupled to the second trench interconnect.

13. The device of claim 12, wherein the first trench interconnect is partially overlapping the second trench interconnect.

14. The device of claim 13, wherein the upper face of the wafer further comprises a third trench interconnect, the third trench interconnect separated from the first trench interconnect, wherein the second trench interconnect is further physically coupled to the third trench interconnect.

15. The device of claim 12, the die further comprising a second metal layer, the second metal layer above the lower face of the die, the second metal layer comprising a third interconnect coupled to the second interconnect by a via.

16. The device of claim 12, wherein the first trench interconnect and the second trench interconnect form a signal path of a coplanar waveguide.

17. An electronics assembly comprising:
a first device comprising a first metal layer at a lower face of the first device;
a second device comprising a second metal layer at an upper face of the first device;
a bonding interface between the first metal layer and the second metal layer; and
a passive circuit element comprising a first metal structure in the first metal layer and a second metal structure in the second metal layer, the first metal structure and the second metal structure bonded at the bonding interface.

18. The electronics assembly of claim 17, wherein the passive circuit element comprises an inductor.

19. The electronics assembly of claim 18, wherein the passive circuit element is a transformer.

20. The electronics assembly of claim 17, wherein the passive circuit element is a filter.
